(19) United States
(12) Patent Application Publication
(10) Pub. No.: US 2024/0004000 A1
(43) Pub. Date: Jan. 4, 2024

(54) MAGNETIC SENSOR

(71) Applicant: Murata Manufacturing Co., Ltd., Nagaokakyo-shi (JP)

(72) Inventor: Takahiro IBUSUKI, Nagaokakyo-shi (JP)

(21) Appl. No.: 18/367,519

(22) Filed: Sep. 13, 2023

Related U.S. Application Data
(63) Continuation of application No. PCT/JP2022/008855, filed on Mar. 2, 2022.

(30) Foreign Application Priority Data
Mar. 30, 2021 (JP) 2021-058082

(51) Int. Cl. G01R 33/09

(52) U.S. Cl. CPC G01R 33/098

(57) ABSTRACT

Each of first and second magnetoresistance effect elements includes an upper electrode, a lower electrode, and a magnetoresistance effect multilayer body between the upper and lower electrodes. In the magnetoresistance effect multilayer body, a magnetized fixed layer having magnetization fixed in a certain direction, a first nonmagnetic layer, and a magnetized free layer whose magnetization direction changes according to a signal magnetic field are sequentially positioned. The upper electrode is provided on a side of the magnetized free layer opposite to the first nonmagnetic layer in a laminating direction of the magnetoresistance effect multilayer body. Each of the upper and lower electrodes includes a magnetic material film including a magnetic material.

### CROSS REFERENCE TO RELATED APPLICATIONS

This application claims the benefit of priority to Japanese Patent Application No. 2021-058082 filed on Mar. 30, 2021 and is a Continuation Application of PCT Application No. PCT/JP2022/008855 filed on Mar. 2, 2022. The entire contents of each application are hereby incorporated herein by reference.

### BACKGROUND OF THE INVENTION

### 1. Field of the Invention

The present invention relates to a magnetic sensor.

### 2. Description of the Related Art

Japanese Patent Laid-Open No. 2018-59730 discloses a configuration of a magnetoresistance effect element. The magnetoresistance effect element described in Japanese Patent Laid-Open No. 2018-59730 includes a plurality of magnetoresistance effect multilayer bodies and a plurality of lead electrodes. The plurality of magnetoresistance effect multilayer bodies are arranged in an array. The plurality of lead electrodes electrically connect the plurality of magnetoresistance effect multilayer bodies in series. The magnetoresistance effect multilayer bodies each have a structure in which an antiferromagnetic layer, a magnetized fixed layer, a nonmagnetic layer, and a free layer are laminated in this order from a lower lead electrode side. In the magnetoresistance effect multilayer body, a resistance value changes according to an angle between a magnetization direction of the free layer and a magnetization direction of the magnetized fixed layer. The resistance value is minimized when this angle is 0°, and the resistance value is maximized when this angle is 180°.

In order to maintain a magnetic field detection accuracy of the magnetoresistance effect element, the magnetization direction of the magnetized fixed layer is required to be constant. When a high-intensity magnetic field is applied to the magnetized fixed layer, the magnetization direction of the magnetized fixed layer changes, and the magnetic field detection accuracy of the magnetoresistance effect element decreases.

### SUMMARY OF THE INVENTION

Preferred embodiments of the present invention provide magnetic sensors that are each able to reduce a magnetic field applied to a magnetized fixed layer to reduce or prevent a decrease in a magnetic field detection accuracy.

A magnetic sensor according to a preferred embodiment of the present invention includes a first magnetoresistance effect element, and a second magnetoresistance effect element. The second magnetoresistance effect element is electrically connected to the first magnetoresistance effect element to define a bridge circuit, and provides a resistance change in a direction opposite to that of the first magnetoresistance effect element when a signal magnetic field is applied. Each of the first magnetoresistance effect element and the second magnetoresistance effect element includes an upper electrode, a lower electrode, and a magnetoresistance effect multilayer body between the upper electrode and the lower electrode. In the magnetoresistance effect multilayer body, a magnetized fixed layer with magnetization that is fixed in a certain direction, a first nonmagnetic layer, and a magnetized free layer whose magnetization direction changes according to the signal magnetic field are sequentially positioned. The upper electrode is provided on a side of the magnetized free layer opposite to the first nonmagnetic layer in a laminating direction of the magnetoresistance effect multilayer body. Each of the upper electrode and the lower electrode includes a magnetic material film including a magnetic material.

According to preferred embodiments of the present invention, it is possible to reduce a magnetic field applied to a magnetized fixed layer to reduce or prevent a decrease in a magnetic field detection accuracy.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view illustrating a configuration of a magnetoresistance effect element included in a magnetic sensor according to a first preferred embodiment of the present invention.

FIG. 2 is a partial side view of the magnetoresistance effect element of FIG. 1 viewed in a direction of an arrow II.

FIG. 3 is a partial side view illustrating a portion III of the magnetoresistance effect element of FIG. 2 in an enlarged manner.

FIG. 4 is a circuit diagram showing an electrical connection of a magnetoresistance effect element included in the magnetic sensor according to the first preferred embodiment of the present invention.

FIG. 5 is a circuit diagram showing a configuration of the magnetic sensor according to the first preferred embodiment of the present invention.

FIG. 6 is a diagram illustrating magnetization directions of an upper electrode, a lower electrode, and a magnetized free layer, when a signal magnetic field is applied, in a direction parallel or substantially parallel to an XY plane, to a magnetoresistance effect element included in the magnetic sensor according to the first preferred embodiment of the present invention.

FIG. 7 is a graph showing a magnetization process of each of an upper electrode and a lower electrode by a signal magnetic field in Example 1.

FIG. 8 is a graph showing a magnetic field intensity of the signal magnetic field in Example 1 applied over each of a central portion, an end portion, and an outer peripheral portion of the magnetoresistance effect element.

FIG. 9 is a partial side view illustrating a configuration of a magnetoresistance effect element included in a magnetic sensor according to a second preferred embodiment of the present invention.

FIG. 10 is a partial side view illustrating an X portion of the magnetoresistance effect element of FIG. 9 in an enlarged manner.

FIG. 11 is a diagram illustrating magnetization directions of an upper electrode, a lower electrode, and a magnetized free layer, when a signal magnetic field is applied, in a direction parallel or substantially parallel to the XY plane, to a magnetoresistance effect element included in the magnetic sensor according to the second preferred embodiment of the present invention.

FIG. 12 is a graph showing a magnetization process of each of an upper electrode and a lower electrode by a signal magnetic field in Example 2.

FIG. 13 is a graph showing a magnetic field intensity of the signal magnetic field in Example 2 applied over each of a central portion, an end portion, and an outer peripheral portion of the magnetoresistance effect element.

FIG. 14 is a partial side view illustrating a configuration of a magnetoresistance effect element included in a magnetic sensor according to a modification of the second preferred embodiment of the present invention.

FIG. 15 is a partial side view illustrating a configuration of a magnetoresistance effect element included in a magnetic sensor according to a third preferred embodiment of the present invention.

FIG. 16 is a circuit diagram showing a configuration of the magnetic sensor according to the third preferred embodiment of the present invention.

FIG. 17 is a diagram illustrating a state in which, to a magnetoresistance effect element included in the magnetic sensor according to the third preferred embodiment of the present invention, a signal magnetic field is applied in a direction orthogonal to the XY plane, while an external magnetic field is applied in a direction parallel or substantially parallel to the XY plane.

FIG. 18 is a graph showing a magnetic field intensity of the signal magnetic field in Example 3 applied over each of a central portion, an end portion, and an outer peripheral portion of the magnetoresistance effect element.

FIG. 19 is a partial side view illustrating a configuration of a magnetoresistance effect element included in a magnetic sensor according to a modification of the third preferred embodiment of the present invention.

### DETAILED DESCRIPTION OF THE PREFERRED EMBODIMENTS

Hereinafter, magnetic sensors according to preferred embodiments of the present invention will be described with reference to the drawings. In the following description of the preferred embodiments, the same or corresponding portions in the drawings are denoted by the same reference numerals, and description thereof will not be repeated.

### First Preferred Embodiment

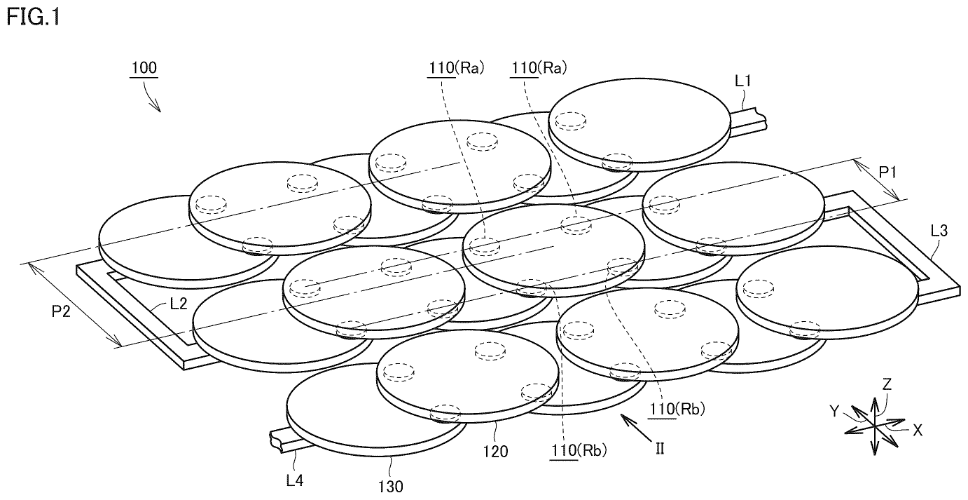

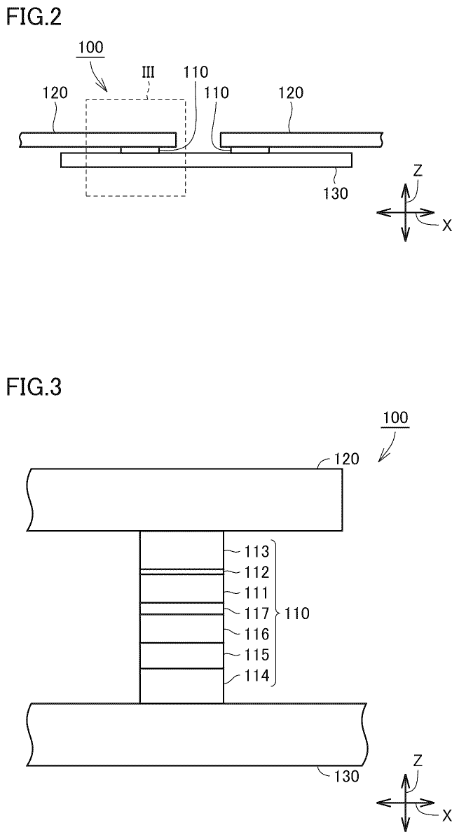

FIG. 1 is a perspective view illustrating a configuration of a magnetoresistance effect element included in a magnetic sensor according to a first preferred embodiment of the present invention. FIG. 2 is a partial side view of the magnetoresistance effect element of FIG. 1 viewed in a direction of an arrow II. FIG. 3 is a partial side view illustrating a portion III of the magnetoresistance effect element of FIG. 2 in an enlarged manner.

As shown in FIGS. 1 to 3, a magnetoresistance effect element 100 included in a magnetic sensor according to the first preferred embodiment of the present invention includes upper electrodes 120, lower electrodes 130, and magnetoresistance effect multilayer bodies 110 sandwiched between upper electrodes 120 and lower electrodes 130.

Upper electrodes 120 are arranged in a matrix at intervals in an X-axis direction and a Y-axis direction. In the present preferred embodiment, each of upper electrodes 120 has a disk shape, for example. A diameter of upper electrode 120 is, for example, about 9 μm. A thickness of upper electrode 120 is, for example, about 0.1 μm. An interval P2 between centers of upper electrodes 120 adjacent to each other is, for example, about 20 μm.

Lower electrodes 130 are arranged in a matrix at intervals in the X-axis direction and the Y-axis direction. In the present preferred embodiment, each of lower electrodes 130 has a disk shape, for example. A diameter of lower electrode 130 is, for example, about 9 μm. A thickness of lower electrode 130 is, for example, about 0.1 μm. Interval P2 between centers of lower electrodes 130 adjacent to each other is, for example, about 20 μm. Lower electrodes 130 face a portion of upper electrodes 120 at an interval in a Z-axis direction.

Each of upper electrodes 120 and lower electrodes 130 includes a magnetic material film including a magnetic material. The magnetic material film may include a single layer of a ferromagnetic layer, or may include a multilayer film including a plurality of layers laminated. The magnetic material film may be, for example, a multilayer film in which a ferromagnetic layer, a nonmagnetic layer, and a ferromagnetic layer are laminated in this order.

The ferromagnetic layer included in the magnetic material film includes a magnetic material including at least one element of, for example, Co, Fe, and Ni as a main component. Examples of the material of the ferromagnetic layer included in the magnetic material film include NiFe, CoFe, CoFeB, and CoFeNi. The nonmagnetic layer included in the magnetic material film includes a nonmagnetic material that exhibits RKKY interaction and includes, for example, Ru, Rh, Cr, Ir, or an alloy thereof as a main component.

Each of magnetoresistance effect multilayer bodies 110 is sandwiched between upper electrode 120 and lower electrode 130 facing each other. Magnetoresistance effect multilayer body 110 has a cylindrical or substantially cylindrical shape. A diameter of magnetoresistance effect multilayer body 110 is, for example, about 3 μm. A thickness of magnetoresistance effect multilayer body 110 is, for example, about 0.035 μm.

In the present preferred embodiment, a first magnetoresistance effect multilayer body Ra and a second magnetoresistance effect multilayer body Rb are disposed at intervals in the Y-axis direction between upper electrode 120 and lower electrode 130 facing each other. An interval P1 between centers of first magnetoresistance effect multilayer body Ra and second magnetoresistance effect multilayer body Rb adjacent to each other is, for example, about 10 μm. A central interval between first magnetoresistance effect multilayer bodies Ra adjacent to each other in the X-axis direction is, for example, about 10 μm. A central interval between second magnetoresistance effect multilayer bodies Rb adjacent to each other in the X-axis direction is, for example, about 10 μm.

In the present preferred embodiment, magnetoresistance effect element 100 is, for example, a tunnel magneto resistance (TMR) element. In magnetoresistance effect multilayer body 110, a magnetized fixed layer having magnetization fixed in a certain direction, a nonmagnetic layer, and a magnetized free layer whose magnetization direction changes according to a signal magnetic field are sequentially laminated.

Specifically, as shown in FIG. 3, an under layer 114, an antiferromagnetic layer 115, a pinned layer 116, a coupled layer 117, a reference layer 111, a first nonmagnetic layer 112, and a magnetized free layer 113 are laminated in this order on lower electrode 130. Here, a multilayer ferri-fixed layer including pinned layer 116, coupled layer 117, and reference layer 111 is a magnetized fixed layer.

Magnetized free layer 113 is a soft ferromagnetic layer whose magnetization direction changes according to an external magnetic field such as a signal magnetic field. Magnetized free layer 113 includes a magnetic material including at least one element of, for example, Co, Fe, and Ni as a main component. For example, magnetized free layer 113 is configured by CoFe, NiFe, CoFeB, a Heusler alloy, or the like. Magnetized free layer 113 may include a single layer or a multilayer ferri-free layer.

First nonmagnetic layer 112 is a nonmagnetic tunnel barrier layer made of MgO, for example, and is a layer thin enough to allow a tunnel current based on quantum mechanics to pass therethrough. First nonmagnetic layer 112 may be made of, for example, oxide or nitride such as Al, Ti, or Hf, other than MgO.

Reference layer 111 is antiferromagnetically coupled to pinned layer 116 with coupled layer 117 interposed therebetween. That is, a magnetization direction of reference layer 111 is antiparallel or substantially antiparallel to a magnetization direction of pinned layer 116. Reference layer 111 is configured by a ferromagnetic material such as CoFe, CoFeB, or a Heulser alloy.

Coupled layer 117 includes a nonmagnetic material that generates RKKY interaction, such as Ru, Ir, Rh, or Cr, for example. Pinned layer 116 includes a ferromagnetic material such as CoFe or CoFeB, for example. Antiferromagnetic layer 115 includes an antiferromagnetic material including Mn, such as, for example, an alloy including any one element of Ni, Fe, Pd, Pt, and Ir and Mn, an alloy including Pd, Pt, and Mn, or an alloy including Cr, Pt, and Mn. Specifically, antiferromagnetic layer 115 includes, for example, IrMn, PtMn, PdPtMn, or CrPtMn.

Under layer 114 is provided to cause crystals of antiferromagnetic layer 115 to appropriately grow. Under layer 114 includes, for example, Ta, W, Mo, Cr, Ti, Zr, Ni, Au, Ag, Cu, Pt, Ru, Ni—Fe, or the like.

As shown in FIG. 1, the plurality of electrode arrays including upper electrodes 120 and lower electrodes 130 arranged in the X-axis direction are connected to each other by wiring made of a nonmagnetic material, and connected in a meandering shape. Specifically, a first wiring L1 is connected to upper electrode 120 located at an end of a first electrode array. Lower electrodes 130 disposed at the ends of the first electrode array and a second electrode array are connected to each other by a second wiring L2. Upper electrodes 120 disposed at the ends of the second electrode array and a third electrode array are connected to each other by a third wiring L3. A fourth wiring L4 is connected to lower electrode 130 located at the end of the third electrode array.

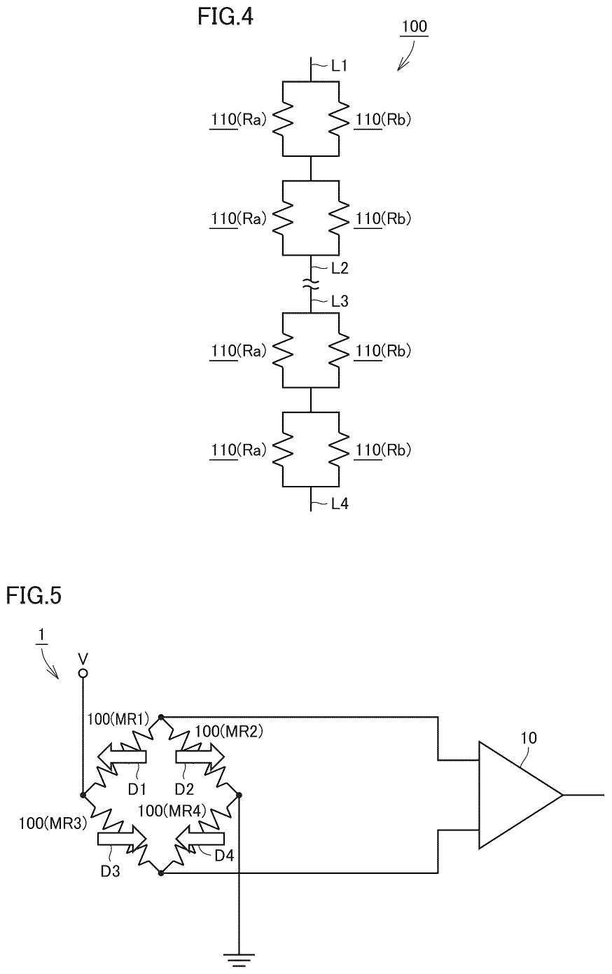

FIG. 4 is a circuit diagram showing an electrical connection of a magnetoresistance effect element included in the magnetic sensor according to the first preferred embodiment of the present invention. As shown in FIG. 4, in magnetoresistance effect element 100, a plurality of parallel connection portions in which first magnetoresistance effect multilayer body Ra and second magnetoresistance effect multilayer body Rb are connected in parallel to each other are connected in series to each other.

FIG. 5 is a circuit diagram showing a configuration of the magnetic sensor according to the first preferred embodiment of the present invention. As shown in FIG. 5, a magnetic sensor 1 according to the first preferred embodiment of the present invention includes a first magnetoresistance effect element 100 (MR1), a second magnetoresistance effect element 100 (MR2), a third magnetoresistance effect element 100 (MR3), and a fourth magnetoresistance effect element 100 (MR4).

First magnetoresistance effect element 100 (MR1), second magnetoresistance effect element 100 (MR2), third magnetoresistance effect element 100 (MR3), and fourth magnetoresistance effect element 100 (MR4) are connected to each other by a full bridge to define a bridge circuit.

Specifically, a first series circuit in which first magnetoresistance effect element 100 (MR1) and second magnetoresistance effect element 100 (MR2) are connected in series with each other and a second series circuit in which third magnetoresistance effect element 100 (MR3) and fourth magnetoresistance effect element 100 (MR4) are connected in series with each other are connected in parallel. A driving voltage V can be applied to the bridge circuit. A midpoint of the first series circuit and a midpoint of the second series circuit are electrically connected to a differential amplifier 10.

Magnetic sensor 1 is not limited to the configuration including a full-bridge circuit, and may include, for example, a half-bridge circuit in which first magnetoresistance effect element 100 (MR1) and second magnetoresistance effect element 100 (MR2) are electrically connected.

In the present preferred embodiment, each of first magnetoresistance effect element 100 (MR1), second magnetoresistance effect element 100 (MR2), third magnetoresistance effect element 100 (MR3), and fourth magnetoresistance effect element 100 (MR4) detects a magnetic field component in a direction orthogonal or substantially orthogonal to the laminating direction (Z-axis direction).

That is, magnetization directions D1 to D4 of reference layer 111 of each of first magnetoresistance effect element 100 (MR1), second magnetoresistance effect element 100 (MR2), third magnetoresistance effect element 100 (MR3), and fourth magnetoresistance effect element 100 (MR4) are parallel or substantially parallel to a XY plane.

As shown in FIG. 5, magnetization direction D1 of reference layer 111 of first magnetoresistance effect element 100 (MR1) and magnetization direction D4 of reference layer 111 of fourth magnetoresistance effect element 100 (MR4), and magnetization direction D2 of reference layer 111 of second magnetoresistance effect element 100 (MR2) and magnetization direction D3 of reference layer 111 of third magnetoresistance effect element 100 (MR3) are antiparallel or substantially antiparallel to each other.

As a result, when a signal magnetic field is applied in a direction parallel or substantially parallel to the XY plane, second magnetoresistance effect element 100 (MR2) shows a resistance change in a direction opposite to that of first magnetoresistance effect element 100 (MR1). Similarly, when a signal magnetic field is applied in a direction parallel or substantially parallel to the XY plane, third magnetoresistance effect element 100 (MR3) shows a resistance change in a direction opposite to that of fourth magnetoresistance effect element 100 (MR4).

As shown in FIG. 3, upper electrode 120 is located on a side of magnetized free layer 113 opposite to first nonmagnetic layer 112 in the laminating direction (Z-axis direction) of magnetoresistance effect multilayer body 110. Upper electrode 120 and magnetized free layer 113 are magnetically coupled to each other.

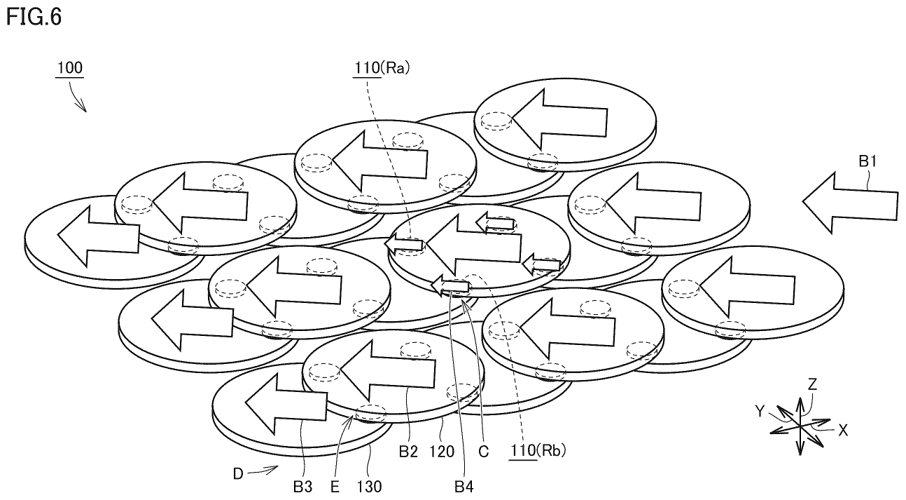

FIG. 6 is a diagram illustrating magnetization directions of an upper electrode, a lower electrode, and a magnetized free layer, when a signal magnetic field is applied, in a direction parallel to an XY plane, to a magnetoresistance effect element included in the magnetic sensor according to the first preferred embodiment of the present invention.

When, to magnetoresistance effect element 100 included in magnetic sensor 1 according to the first preferred embodiment of the present invention, a signal magnetic field B1 is applied in a direction parallel or substantially parallel to the XY plane as shown in FIG. 6, signal magnetic field B1 mainly flows into each of upper electrode 120 and lower electrode 130 having higher magnetic permeability than that of magnetoresistance effect multilayer body 110. Signal magnetic field B1 hardly flows into magnetoresistance effect multilayer body 110 until each of upper electrode 120 and lower electrode 130 reaches saturated magnetization. After each of upper electrode 120 and lower electrode 130 reaches saturated magnetization, signal magnetic field B1 flows into magnetoresistance effect multilayer body 110.

As shown in FIG. 6, upper electrode 120 is magnetized by signal magnetic field B1 in a magnetization direction B2 along an application direction of signal magnetic field B1. Lower electrode 130 is magnetized by signal magnetic field B1 in a magnetization direction B3 along the application direction of signal magnetic field B1. Since magnetized free layer 113 is magnetically coupled to upper electrode 120, magnetizing upper electrode 120 in magnetization direction B2 causes magnetized free layer 113 to be magnetized in a magnetization direction B4 coinciding with magnetization direction B2.

In the present preferred embodiment, each of upper electrode 120 and lower electrode 130 defines and functions as a magnetic shield, and thus it is possible to reduce signal magnetic field B1 flowing into magnetoresistance effect multilayer body 110, to reduce signal magnetic field B1 applied to the magnetized fixed layer, and to reduce or prevent a decrease in a magnetic field detection accuracy of magnetoresistance effect element 100. Further, even in a state in which signal magnetic field B1 applied to magnetoresistance effect multilayer body 110 is reduced, magnetization direction B4 of magnetized free layer 113 magnetically coupled to upper electrode 120 coincides with magnetization direction B2 of upper electrode 120, and thus, a magnetoresistance change corresponding to the application direction of signal magnetic field B1 occurs in magnetoresistance effect element 100. Therefore, using magnetic sensor 1, it is possible to detect the application direction of signal magnetic field B1. That is, magnetic sensor 1 can detect a rotation angle of a magnetic material or the like that rotates around a rotation axis while generating signal magnetic field B1.

Here, simulation analysis in which a signal magnetic field is applied to magnetoresistance effect element 100 of magnetic sensor 1 according to Example 1 of the present preferred embodiment will be described.

As a simulation analysis condition, each of upper electrode 120 and lower electrode 130 includes 80 Ni—Fe (permalloy). The thickness of each of upper electrode 120 and lower electrode 130 was about 0.1 μm. The diameter of each of upper electrode 120 and lower electrode 130 was about 9 μm. The thickness of magnetoresistance effect multilayer body 110 was about 0.035 μm. The diameter of magnetoresistance effect multilayer body 110 was about 3 μm.

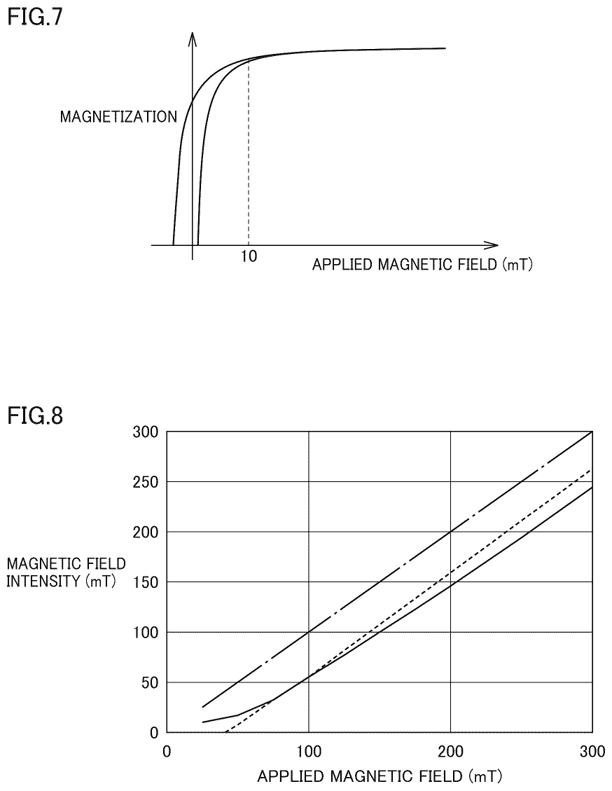

FIG. 7 is a graph showing a magnetization process of each of an upper electrode and a lower electrode by a signal magnetic field in example 1. In FIG. 7, a vertical axis represents magnetization, and a horizontal axis represents a signal magnetic field (mT). As shown in FIG. 7, each of upper electrode 120 and lower electrode 130 reaches saturated magnetization when signal magnetic field B1 becomes greater than or equal to about 10 mT. FIG. 8 is a graph showing a magnetic field intensity of the signal magnetic field in example 1 applied over each of a central portion, an end portion, and an outer peripheral portion of the magnetoresistance effect element. In FIG. 8, a vertical axis represents the magnetic field intensity (mT), and a horizontal axis represents the signal magnetic field (mT). In FIG. 8, the magnetic field intensity extending to a central portion C of magnetoresistance effect element 100 illustrated in FIG. 6 is indicated by a solid line, the magnetic field intensity extending to an end portion E of magnetoresistance effect element 100 illustrated in FIG. 6 is indicated by a dotted line, and the magnetic field intensity extending to an outer peripheral portion D of magnetoresistance effect element 100 illustrated in FIG. 6 is indicated by an alternate long and short dash line. Each of central portion C, end portion E, and outer peripheral portion D of magnetoresistance effect element 100 is located in the XY plane where reference layer 111 is located.

As shown in FIG. 8, signal magnetic field B1 acted on outer peripheral portion D of magnetoresistance effect element 100 with an original magnetic field intensity. On end portion E of magnetoresistance effect element 100, signal magnetic field B1 acted with reduced magnetic field intensity by about 40 mT. On central portion C of magnetoresistance effect element 100, signal magnetic field B1 acted with reduced magnetic field intensity by about 50 mT.

From the above simulation results, it was confirmed that the magnetic field can be hardly applied to the magnetized fixed layer until each of upper electrode 120 and lower electrode 130 reaches saturated magnetization, and the magnetic field applied to the magnetized fixed layer can be reduced by about 40 mT to about mT even after each of upper electrode 120 and lower electrode 130 reaches saturated magnetization.

In magnetic sensor 1 according to the present preferred embodiment, each of upper electrode 120 and lower electrode 130 includes a magnetic material film including a magnetic material. As a result, each of upper electrode 120 and lower electrode 130 defines and functions as a magnetic shield, and thus it is possible to reduce signal magnetic field B1 flowing into magnetoresistance effect multilayer body 110, to reduce signal magnetic field B1 applied to the magnetized fixed layer, and to reduce or prevent a decrease in a magnetic field detection accuracy of magnetoresistance effect element 100. In addition, it is also possible to reduce or prevent an external magnetic field other than signal magnetic field B1 from flowing into magnetoresistance effect multilayer body 110. This also makes it possible to reduce or prevent a decrease in magnetic field detection accuracy of magnetoresistance effect element 100. As a result, magnetic sensor 1 can detect signal magnetic field B1 with high accuracy.

In magnetic sensor 1 according to the present preferred embodiment, each of first magnetoresistance effect element 100 (MR1) and second magnetoresistance effect element 100 (MR2) detects a magnetic field component in a direction (direction in the XY plane) orthogonal or substantially orthogonal to the laminating direction (Z-axis direction), and upper electrode 120 and magnetized free layer 113 are magnetically coupled to each other. As a result, since magnetization direction B4 of magnetized free layer 113 magnetically coupled to upper electrode 120 coincides with magnetization direction B2 of upper electrode 120, a magnetoresistance change corresponding to the application direction of signal magnetic field B1 occurs in each of first magnetoresistance effect element 100 (MR1) and second magnetoresistance effect element 100 (MR2). Since second magnetoresistance effect element 100 (MR2) provides a resistance change in a direction opposite to that of first magnetoresistance effect element 100 (MR1), it is possible to detect the application direction of signal magnetic field B1 in the XY plane with high accuracy by increasing an amount of change in an intermediate potential between first magnetoresistance effect element 100 (MR1) and second magnetoresistance effect element 100 (MR2) in the bridge circuit due to signal magnetic field B1.

In the present preferred embodiment, each of upper electrode 120 and lower electrode 130 has a disk shape. As a result, it is possible to prevent anisotropy from occurring in detection characteristics of signal magnetic field B1 by magnetic sensor 1.

The magnetic material film defining lower electrode 130 may include a multilayer film in which a plurality of layers including an antiferromagnetic layer are laminated. In this case, since the magnetic permeability of lower electrode 130 is reduced by exchange coupling, lower electrode 130 can be made less likely to reach saturated magnetization. As a result, it is possible to reduce signal magnetic field B1 flowing into magnetoresistance effect multilayer body 110 up to a range where the intensity of signal magnetic field B1 is relatively high. Therefore, magnetic sensor 1 can detect signal magnetic field B1 with high accuracy up to a range where the intensity of signal magnetic field B1 is relatively high.

### Second Preferred Embodiment

Hereinafter, a magnetic sensor according to a second preferred embodiment of the present invention will be described with reference to the drawings. The magnetic sensor according to the second preferred embodiment of the present invention is different from magnetic sensor 1 according to the first preferred embodiment of the present invention mainly in that a magnetic material film including an upper electrode includes a multilayer film including an antiferromagnetic layer, and thus the description of the same or substantially the same configuration as magnetic sensor 1 according to the first preferred embodiment of the present invention will not be repeated.

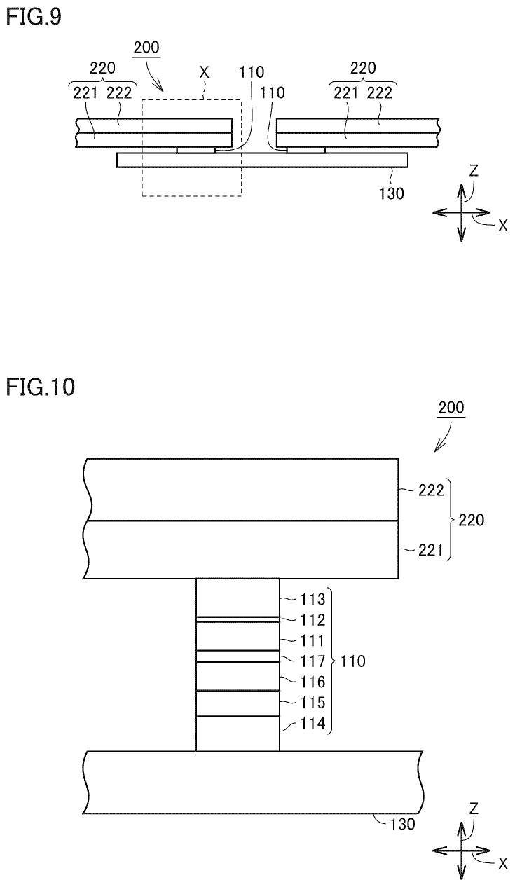

FIG. 9 is a partial side view illustrating a configuration of a magnetoresistance effect element included in a magnetic sensor according to the second preferred embodiment of the present invention. FIG. 10 is a partial side view illustrating an X portion of the magnetoresistance effect element of FIG. 9 in an enlarged manner.

As shown in FIGS. 9 and 10, a magnetoresistance effect element 200 included in a magnetic sensor according to the second preferred embodiment of the present invention includes upper electrodes 220, lower electrodes 130, and magnetoresistance effect multilayer bodies 110 sandwiched between upper electrodes 220 and lower electrodes 130.

Upper electrodes 220 are arranged in a matrix at intervals in the X-axis direction and the Y-axis direction. In the present preferred embodiment, each of upper electrodes 220 has a disk shape, for example. However, the shape of upper electrode 220 is not limited to the cylindrical shape, and may be a prismatic shape, for example. A diameter of upper electrode 220 is, for example, about 9 μm. A thickness of upper electrode 220 is, for example, about 0.2 μm. An interval between centers of upper electrodes 220 adjacent to each other is, for example, about 20 μm.

A first magnetic material film defining upper electrode 220 includes a multilayer film in which a plurality of layers including an antiferromagnetic layer 222 are laminated. In the present preferred embodiment, the first magnetic material film is a multilayer film in which a ferromagnetic layer 221 and antiferromagnetic layer 222 are laminated in this order.

Antiferromagnetic layer 222 includes an antiferromagnetic material including Mn, such as, for example, an alloy including any one element of Ni, Fe, Pd, Pt, and Ir and Mn, an alloy including Pd, Pt, and Mn, or an alloy including Cr, Pt, and Mn.

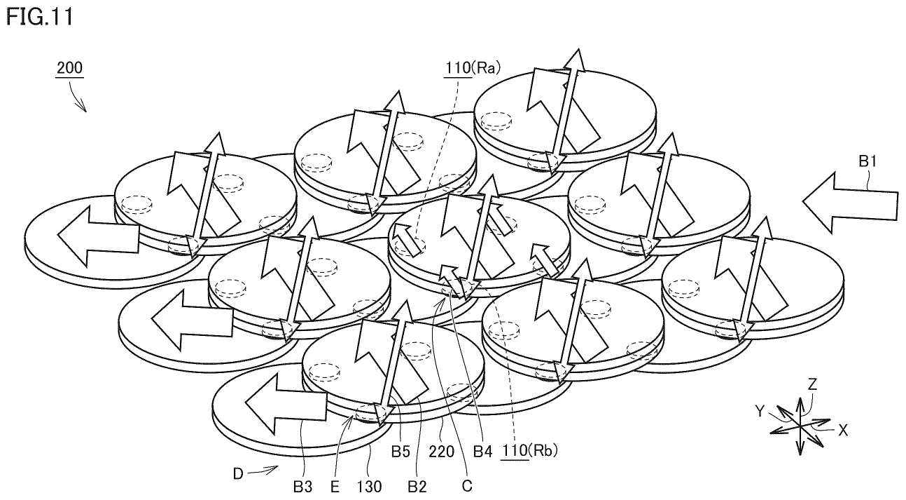

FIG. 11 is a diagram illustrating magnetization directions of an upper electrode, a lower electrode, and a magnetized free layer, when a signal magnetic field is applied, in a direction parallel or substantially parallel to the XY plane, to a magnetoresistance effect element included in the magnetic sensor according to the second preferred embodiment of the present invention.

As shown in FIG. 11, in upper electrode 220, a magnetization direction B5 of upper electrode 220 is fixed by exchange coupling between ferromagnetic layer 221 and antiferromagnetic layer 222. Magnetization direction B5 is parallel or substantially parallel to the XY plane.

When, to magnetoresistance effect element 200 included in the magnetic sensor according to the second preferred embodiment of the present invention, signal magnetic field B1 is applied in a direction orthogonal or substantially orthogonal to magnetization direction B5 in the XY plane as shown in FIG. 11, signal magnetic field B1 mainly flows into each of upper electrode 220 and lower electrode 130 having higher magnetic permeability than that of magnetoresistance effect multilayer body 110. Signal magnetic field B1 hardly flows into magnetoresistance effect multilayer body 110 until each of upper electrode 220 and lower electrode 130 reaches saturated magnetization. After each of upper electrode 220 and lower electrode 130 reaches saturated magnetization, signal magnetic field B1 flows into magnetoresistance effect multilayer body 110.

In the present preferred embodiment, the magnetic material film defining upper electrode 220 includes a multilayer film in which a plurality of layers including an antiferromagnetic layer are laminated, and the magnetic permeability of upper electrode 220 is reduced by exchange coupling. Therefore, upper electrode 220 is less likely to reach saturated magnetization. As a result, it is possible to reduce signal magnetic field B1 flowing into magnetoresistance effect multilayer body 110 up to a range where the intensity of signal magnetic field B1 is relatively high.

As shown in FIG. 11, upper electrode 220 is magnetized in magnetization direction B2 in which magnetization direction B5 and the application direction of signal magnetic field B1 are combined. Until upper electrode 220 reaches saturated magnetization, magnetization direction B2 changes according to the intensity of signal magnetic field B1. Lower electrode 130 is magnetized by signal magnetic field B1 in a magnetization direction B3 along the application direction of signal magnetic field B1. Since magnetized free layer 113 is magnetically coupled to upper electrode 220, magnetizing upper electrode 220 in magnetization direction B2 causes magnetized free layer 113 to be magnetized in magnetization direction B4 coinciding with magnetization direction B2.

In the present preferred embodiment, each of upper electrode 220 and lower electrode 130 defines and functions as a magnetic shield, and thus it is possible to reduce signal magnetic field B1 flowing into magnetoresistance effect multilayer body 110, to reduce signal magnetic field B1 applied to the magnetized fixed layer, and to reduce or prevent a decrease in a magnetic field detection accuracy of magnetoresistance effect element 200.

Further, even in a state in which signal magnetic field B1 applied to magnetoresistance effect multilayer body 110 is reduced, magnetization direction B4 of magnetized free layer 113 magnetically coupled to upper electrode 220 coincides with magnetization direction B2 of upper electrode 120, and thus, a magnetoresistance change corresponding to the intensity of signal magnetic field B1 occurs in magnetoresistance effect element 200. Therefore, the magnetic sensor according to the present preferred embodiment can detect the intensity of signal magnetic field B1. That is, the magnetic sensor according to the present preferred embodiment can detect a distance from a magnetic material or the like that moves closer or farther away while generating signal magnetic field B1.

Here, simulation analysis in which a signal magnetic field is applied to magnetoresistance effect element 200 of the magnetic sensor according to Example 2 of the present preferred embodiment will be described.

As a simulation analysis condition, each of ferromagnetic layer 221 of upper electrode 220 and lower electrode 130 included 80 Ni—Fe (permalloy). Antiferromagnetic layer 222 of upper electrode 220 included PtMn. The thickness of upper electrode 220 was about 0.2 μm. The thickness of lower electrode 130 was about 0.1 μm. The diameter of each of upper electrode 220 and lower electrode 130 was about 9 μm. The thickness of magnetoresistance effect multilayer body 110 was about 0.035 μm. The diameter of magnetoresistance effect multilayer body 110 was about 3 μm.

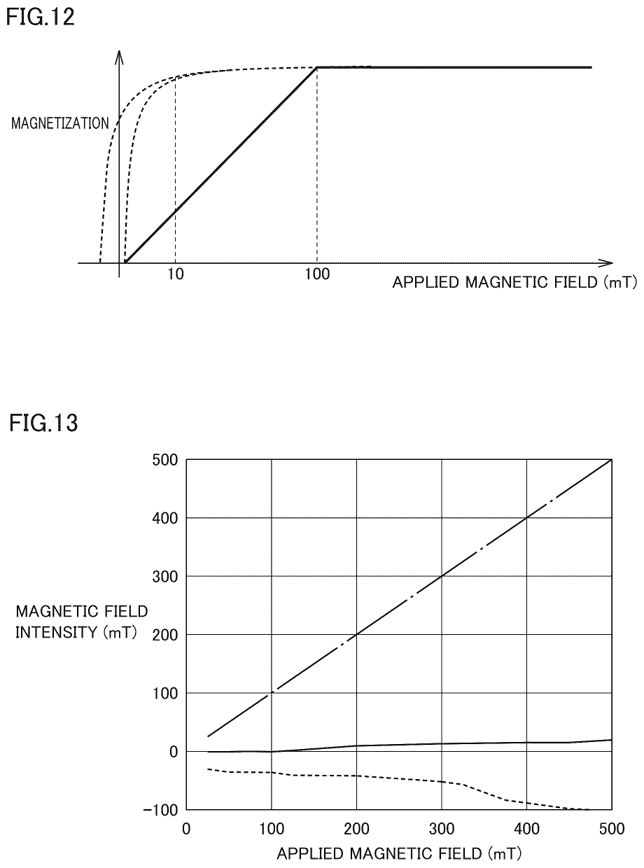

FIG. 12 is a graph showing a magnetization process of each of an upper electrode and a lower electrode by a signal magnetic field in Example 2. In FIG. 12, a vertical axis represents magnetization, and a horizontal axis represents a signal magnetic field (mT). In addition, the magnetization process of upper electrode 220 is indicated by a solid line, and the magnetization process of lower electrode 130 is indicated by a dotted line.

As shown in FIG. 12, lower electrode 130 reaches saturated magnetization when signal magnetic field B1 becomes greater than or equal to about 10 mT. Upper electrode 220 is magnetized in proportion to intensity of signal magnetic field B1 in a range in which signal magnetic field B1 is less than about 100 mT, and reaches saturated magnetization when signal magnetic field B1 becomes greater than or equal to about 100 mT.

FIG. 13 is a graph showing a magnetic field intensity of the signal magnetic field in Example 2 applied over each of a central portion, an end portion, and an outer peripheral portion of the magnetoresistance effect element. In FIG. 13, a vertical axis represents the magnetic field intensity (mT), and a horizontal axis represents the signal magnetic field (mT). In FIG. 13, the magnetic field intensity extending to a central portion C of magnetoresistance effect element 200 illustrated in FIG. 11 is indicated by a solid line, the magnetic field intensity extending to an end portion E of magnetoresistance effect element 200 illustrated in FIG. 11 is indicated by a dotted line, and the magnetic field intensity extending to an outer peripheral portion D of magnetoresistance effect element 200 illustrated in FIG. 11 is indicated by an alternate long and short dash line. Each of central portion C, end portion E, and outer peripheral portion D of magnetoresistance effect element 200 is located in the XY plane where reference layer 111 is located.

As shown in FIG. 13, signal magnetic field B1 acted on outer peripheral portion D of magnetoresistance effect element 200 with an original magnetic field intensity. On end portion E of magnetoresistance effect element 200, A magnetic field in a direction opposite to the application direction of signal magnetic field B1 acted with an intensity of about ⅕ of signal magnetic field B1. On central portion C of magnetoresistance effect element 200, magnetic field intensity reduced down to about 1/25 of signal magnetic field B1 acted.

From the above simulation results, it was confirmed that the magnetic field can be hardly applied to the magnetized fixed layer until upper electrode 220 reaches saturated magnetization, and the magnetic field applied to the magnetized fixed layer can be reduced to about 1/25 of the intensity of signal magnetic field B1 even after upper electrode 220 reaches saturated magnetization.

In the magnetic sensor according to the present preferred embodiment, since the magnetic material film of upper electrode 220 includes a multilayer film in which a plurality of layers including an antiferromagnetic layer are laminated, the magnetic permeability of upper electrode 220 is reduced by exchange coupling. Therefore, upper electrode 220 can be made less likely to reach saturated magnetization. As a result, it is possible to reduce signal magnetic field B1 flowing into magnetoresistance effect multilayer body 110 up to a range where the intensity of signal magnetic field B1 is relatively high. Therefore, magnetic sensor 1 can detect signal magnetic field B1 with high accuracy up to a range where the intensity of signal magnetic field B1 is relatively high.

In addition, since magnetization direction B5 of upper electrode 220 is fixed by exchange coupling, upper electrode 220 is magnetized in magnetization direction B2 in which magnetization direction B5 and the application direction of signal magnetic field B1 are combined when signal magnetic field B1 is applied. Until upper electrode 220 reaches saturated magnetization, magnetization direction B2 changes according to the intensity of signal magnetic field B1. Since magnetization direction B4 of magnetized free layer 113 magnetically coupled to upper electrode 220 coincides with magnetization direction B2 of upper electrode 120, a magnetoresistance change corresponding to the intensity of signal magnetic field B1 occurs in magnetoresistance effect element 200. Therefore, the magnetic sensor according to the present preferred embodiment can detect the intensity of signal magnetic field B1 until upper electrode 220 reaches saturated magnetization.

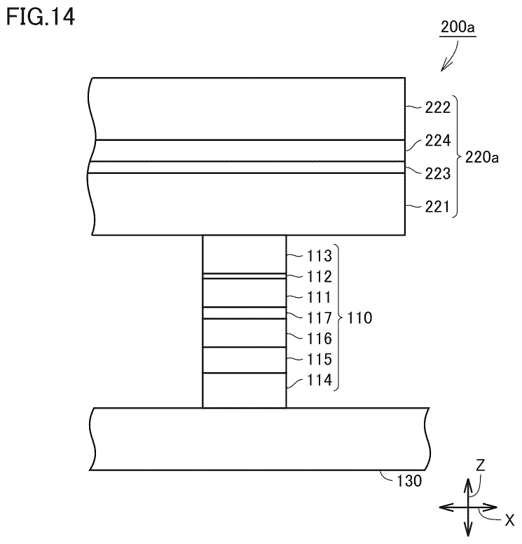

The configuration of the first magnetic material film of upper electrode 220 is not limited to the above example. FIG. 14 is a partial side view illustrating a configuration of a magnetoresistance effect element included in a magnetic sensor according to a modification of the second preferred embodiment of the present invention.

As shown in FIG. 14, a magnetoresistance effect element 200a included in a magnetic sensor according to a modification of the second preferred embodiment of the present invention includes upper electrodes 220a, lower electrodes 130, and magnetoresistance effect multilayer bodies 110 sandwiched between upper electrodes 220a and lower electrodes 130.

The first magnetic material film of upper electrode 220a is a multilayer film in which ferromagnetic layer 221, a nonmagnetic layer 223, a ferromagnetic layer 224, and antiferromagnetic layer 222 are laminated in this order. Nonmagnetic layer 223 includes a nonmagnetic material that generates RKKY interaction such as, for example, Ru. By interposing nonmagnetic layer 223 made of, for example, Ru or the like in the first magnetic material film, magnetization direction B5 of upper electrode 220a can be reversed by about 180°. As a result, upper electrode 220a can be made even less likely to reach saturated magnetization. The magnetic sensor according to the present modification can detect the intensity of signal magnetic field B1 up to a relatively high range in which upper electrode 220a reaches saturated magnetization.

### Third Preferred Embodiment

Hereinafter, a magnetic sensor according to a third preferred embodiment of the present invention will be described with reference to the drawings. The magnetic sensor according to the third preferred embodiment of the present invention is different from magnetic sensor 1 according to the first preferred embodiment of the present invention mainly in that the magnetoresistance effect element detects a magnetic field component in the laminating direction (Z-axis direction), and the upper electrode and the magnetized free layer are not magnetically coupled to each other, and thus the description of the same or substantially the same configuration as magnetic sensor 1 according to the first preferred embodiment of the present invention will not be repeated.

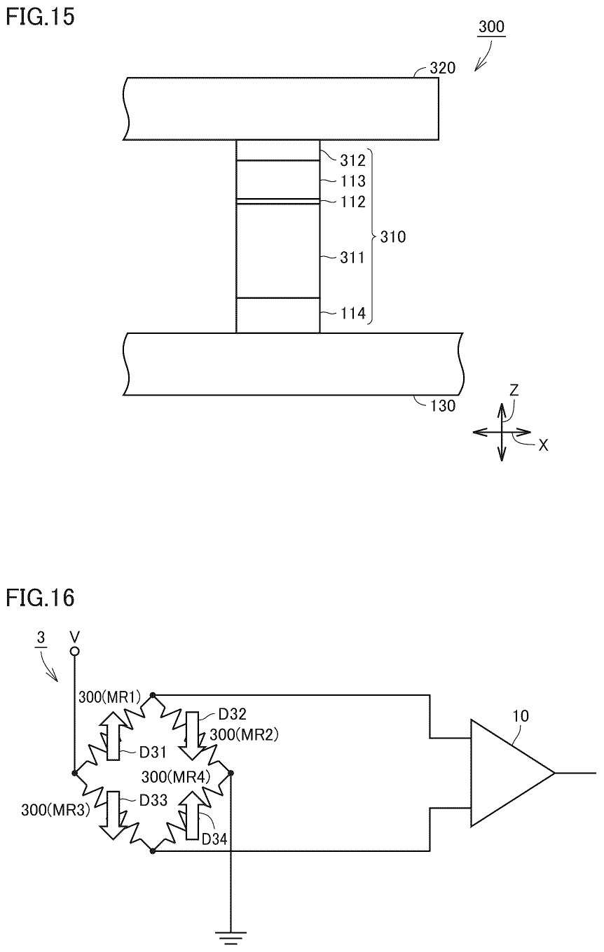

FIG. 15 is a partial side view illustrating a configuration of a magnetoresistance effect element included in a magnetic sensor according to the third preferred embodiment of the present invention. As shown in FIG. 15, a magnetoresistance effect element 300 included in a magnetic sensor according to the third preferred embodiment of the present invention includes upper electrodes 320, lower electrodes 130, and magnetoresistance effect multilayer bodies 310 sandwiched between upper electrodes 320 and lower electrodes 130.

Upper electrodes 320 are arranged in a matrix at intervals in the X-axis direction and the Y-axis direction. In the present preferred embodiment, each of upper electrodes 320 has a disk shape. A diameter of upper electrode 320 is, for example, about 9 μm. A thickness of upper electrode 320 is, for example, about 0.1 μm. An interval between centers of upper electrodes 320 adjacent to each other is, for example, about 20 μm.

Upper electrode 320 includes a magnetic material film including a magnetic material. The magnetic material film may include a single layer of a ferromagnetic layer, or may include a multilayer film including a plurality of layers laminated. The magnetic material film may be, for example, a multilayer film in which a ferromagnetic layer, a nonmagnetic layer, and a ferromagnetic layer are laminated in this order.

Each of magnetoresistance effect multilayer bodies 310 is sandwiched between upper electrode 320 and lower electrode 130 facing each other. Magnetoresistance effect multilayer body 310 has a cylindrical or substantially cylindrical shape, for example. A diameter of magnetoresistance effect multilayer body 310 is, for example, about 3 μm. A thickness of magnetoresistance effect multilayer body 310 is, for example, about 0.035 μm.

In magnetoresistance effect multilayer body 310, a magnetized fixed layer 311 having magnetization that is fixed in a certain direction, first nonmagnetic layer 112, and magnetized free layer 113 whose magnetization direction changes according to the signal magnetic field are sequentially laminated.

Specifically, under layer 114, magnetized fixed layer 311, first nonmagnetic layer 112, magnetized free layer 113, and a second nonmagnetic layer 312 are laminated in this order on lower electrode 130. That is, second nonmagnetic layer 312 is provided between upper electrode 320 and magnetized free layer 113.

Magnetized fixed layer 311 includes a single layer of a ferromagnetic material such as TbFeCo, for example. Magnetized fixed layer 311 include a multilayer film in which, for example, Pd, Co, and the like are laminated, or a multilayer film in which, for example, Pt, Co, and the like are laminated. The magnetization direction of magnetized fixed layer 311 is parallel or substantially parallel to the laminating direction (Z-axis direction) of magnetoresistance effect multilayer body 310.

Second nonmagnetic layer 312 includes any one metal of, for example, Ru, Cu, Ti, Ta, Pt, Pd, Au, and Ag, an alloy including any one of these, or a multiple-layer film of these metals.

FIG. 16 is a circuit diagram showing a configuration of the magnetic sensor according to the third preferred embodiment of the present invention. As shown in FIG. 16, a magnetic sensor 3 according to the third preferred embodiment of the present invention includes a first magnetoresistance effect element 300 (MR1), a second magnetoresistance effect element 300 (MR2), a third magnetoresistance effect element 300 (MR3), and a fourth magnetoresistance effect element 300 (MR4).

First magnetoresistance effect element 300 (MR1), second magnetoresistance effect element 300 (MR2), third magnetoresistance effect element 300 (MR3), and fourth magnetoresistance effect element 300 (MR4) are connected to each other by a full bridge to define a bridge circuit.

Magnetic sensor 3 is not limited to the configuration including a full-bridge circuit, and may include, for example, a half-bridge circuit in which first magnetoresistance effect element 300 (MR1) and second magnetoresistance effect element 300 (MR2) are electrically connected.

In the present preferred embodiment, each of first magnetoresistance effect element 300 (MR1), second magnetoresistance effect element 300 (MR2), third magnetoresistance effect element 300 (MR3), and fourth magnetoresistance effect element 300 (MR4) detects a magnetic field component in the laminating direction (Z-axis direction).

That is, magnetization directions D31 to D34 of magnetized fixed layer 311 of each of first magnetoresistance effect element 300 (MR1), second magnetoresistance effect element 300 (MR2), third magnetoresistance effect element 300 (MR3), and fourth magnetoresistance effect element 300 (MR4) are orthogonal or substantially orthogonal to the XY plane.

As shown in FIG. 16, magnetization direction D31 of magnetized fixed layer 311 of first magnetoresistance effect element 300 (MR1) and magnetization direction D34 of magnetized fixed layer 311 of fourth magnetoresistance effect element 300 (MR4), and magnetization direction D32 of magnetized fixed layer 311 of second magnetoresistance effect element 300 (MR2) and magnetization direction D33 of magnetized fixed layer 311 of third magnetoresistance effect element 300 (MR3) are antiparallel or substantially antiparallel to each other.

As a result, when a signal magnetic field is applied in a direction orthogonal or substantially orthogonal to the XY plane, second magnetoresistance effect element 300 (MR2) shows a resistance change in a direction opposite to that of first magnetoresistance effect element 300 (MR1). Similarly, when a signal magnetic field is applied in a direction orthogonal or substantially orthogonal to the XY plane, third magnetoresistance effect element 300 (MR3) shows a resistance change in a direction opposite to that of fourth magnetoresistance effect element 300 (MR4).

As shown in FIG. 15, since second nonmagnetic layer 312 is provided between upper electrode 320 and magnetized free layer 113, upper electrode 320 and magnetized free layer 113 are not magnetically coupled to each other.

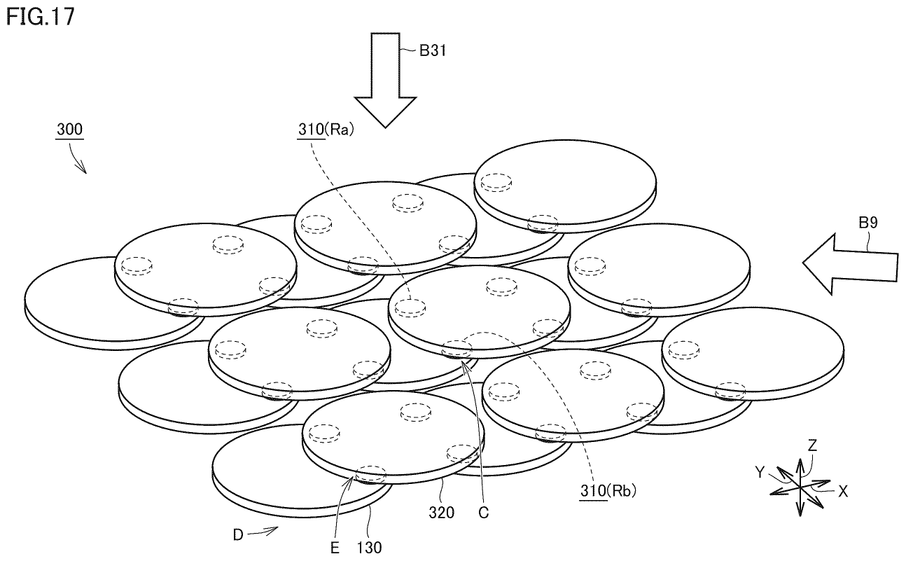

FIG. 17 is a diagram illustrating a state in which, to a magnetoresistance effect element included in the magnetic sensor according to the third preferred embodiment of the present invention, a signal magnetic field is applied in a direction orthogonal or substantially orthogonal to the XY plane, while an external magnetic field is applied in a direction parallel or substantially parallel to the XY plane.

When, to magnetoresistance effect element 300 included in magnetic sensor 3 according to the third preferred embodiment of the present invention, an external magnetic field B9 is applied in a direction parallel or substantially parallel to the XY plane as shown in FIG. 17, external magnetic field B9 mainly flows into each of upper electrode 320 and lower electrode 130 having higher magnetic permeability than that of magnetoresistance effect multilayer body 310. External magnetic field B9 hardly flows into magnetoresistance effect multilayer body 310 until each of upper electrode 320 and lower electrode 130 reaches saturated magnetization. After each of upper electrode 320 and lower electrode 130 reaches saturated magnetization, external magnetic field B9 flows into magnetoresistance effect multilayer body 310.

Since the magnetic permeability in the Z-axis direction of each of upper electrode 320 and lower electrode 130 is low, when a signal magnetic field B31 is applied in a direction orthogonal or substantially orthogonal to the XY plane as shown in FIG. 17, signal magnetic field B31 passes through upper electrode 320 and flows into magnetoresistance effect multilayer body 310. As a result, magnetized free layer 113 is magnetized along the application direction of signal magnetic field B31. Since magnetized free layer 113 is not magnetically coupled to upper electrode 320, the magnetization direction of magnetized free layer 113 is not affected by the magnetization direction of upper electrode 320 even if upper electrode 320 is magnetized by external magnetic field B9.

In the present preferred embodiment, each of upper electrode 320 and lower electrode 130 defines and functions as a magnetic shield, and thus it is possible to reduce external magnetic field B9 flowing into magnetoresistance effect multilayer body 310, to reduce external magnetic field B9 applied to magnetized fixed layer 311, and to reduce or prevent a decrease in a magnetic field detection accuracy of magnetoresistance effect element 300.

In addition, since magnetized free layer 113 is not magnetically coupled to upper electrode 320, it is possible to detect the intensity of signal magnetic field B31 that has passed through upper electrode 320 and flowed into magnetoresistance effect multilayer body 310.

Here, simulation analysis in which a signal magnetic field is applied in the Z-axis direction to magnetoresistance effect element 300 of magnetic sensor 3 according to Example 3 of the present preferred embodiment will be described.

As a simulation analysis condition, each of upper electrode 320 and lower electrode 130 included 80 Ni—Fe (permalloy). The thickness of each of upper electrode 320 and lower electrode 130 was about 0.1 μm. The diameter of each of upper electrode 320 and lower electrode 130 was about 9 μm. The thickness of magnetoresistance effect multilayer body 310 was about 0.035 μm. The diameter of magnetoresistance effect multilayer body 310 was about 3 μm.

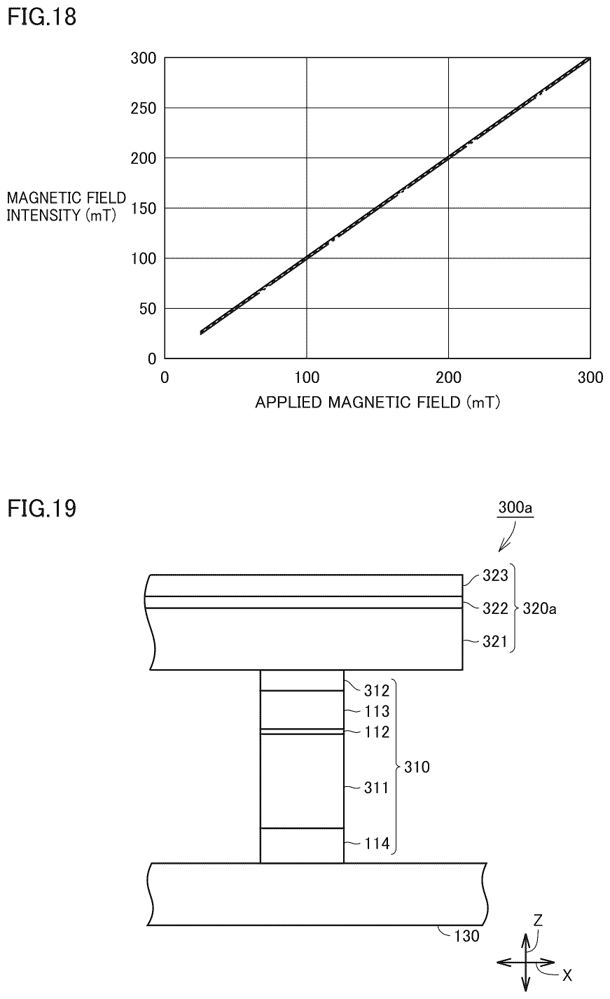

FIG. 18 is a graph showing a magnetic field intensity of the signal magnetic field in Example 3 applied over each of a central portion, an end portion, and an outer peripheral portion of the magnetoresistance effect element. In FIG. 18, a vertical axis represents the magnetic field intensity (mT), and a horizontal axis represents the signal magnetic field (mT). In FIG. 18, the magnetic field intensity extending to central portion C of magnetoresistance effect element 300 illustrated in FIG. 17 is indicated by a solid line, the magnetic field intensity extending to end portion E of magnetoresistance effect element 300 illustrated in FIG. 17 is indicated by a dotted line, and the magnetic field intensity extending to outer peripheral portion D of magnetoresistance effect element 300 illustrated in FIG. 17 is indicated by an alternate long and short dash line. Each of central portion C, end portion E, and outer peripheral portion D of magnetoresistance effect element 300 is located in the XY plane where magnetized fixed layer 311 is located.

As shown in FIG. 18, signal magnetic field B31 acted on each of central portion C, end portion E, and outer peripheral portion D of magnetoresistance effect element 300 with an original magnetic field intensity. From the above simulation results, it was confirmed that the intensity of signal magnetic field B31 can be detected by magnetoresistance effect element 300.

In magnetic sensor 3 according to the present preferred embodiment, it is possible to detect the intensity of signal magnetic field B31 applied in the direction orthogonal to the XY plane while reducing or preventing a decrease in the magnetic field detection accuracy of magnetoresistance effect element 300 due to external magnetic field B9 applied in the direction within the XY plane.

The configuration of the first magnetic material film constituting upper electrode 320 is not limited to the above example. FIG. 19 is a partial side view illustrating a configuration of a magnetoresistance effect element included in a magnetic sensor according to a modification of the third preferred embodiment of the present invention.

As shown in FIG. 19, a magnetoresistance effect element 300a included in a magnetic sensor according to a modification of the third preferred embodiment of the present invention includes upper electrodes 320a, lower electrodes 130, and magnetoresistance effect multilayer bodies 310 sandwiched between upper electrodes 320a and lower electrodes 130.

The first magnetic material film of upper electrode 320a is a multilayer film in which a ferromagnetic layer 321, a nonmagnetic layer 322, and a ferromagnetic layer 323 are laminated in this order. Nonmagnetic layer 322 includes a nonmagnetic highly conductive material such as Ru, for example. An antiferromagnetic layer may be further laminated on ferromagnetic layer 323.

By interposing nonmagnetic layer 322 made of Ru or the like, for example, in the first magnetic material film, the magnetization direction of upper electrode 320a can be reversed by about 180°. As a result, upper electrode 320a can be made even less likely to reach saturated magnetization. The magnetic sensor according to the present modification can reduce external magnetic field B9 flowing into magnetoresistance effect multilayer body 310 up to a range where the intensity of external magnetic field B9 is relatively high.

In the description of the above-described preferred embodiments, configurations that can be combined may be combined with each other. In the above-described preferred embodiments, the case where the magnetoresistance effect element is a TMR element has been described, but the present invention is not limited to such a case, and for example, the magnetoresistance effect element may be a giant magnetoresistance (GMR) element. In this case, first nonmagnetic layer 112 needs to be a highly conductive nonmagnetic material layer such as Cu, Au, or Cr, for example, instead of a tunnel barrier layer.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A magnetic sensor comprising:
a first magnetoresistance effect element; and
a second magnetoresistance effect element electrically connected to the first magnetoresistance effect element to define a bridge circuit, the second magnetoresistance effect element providing a resistance change in a direction opposite to a resistance change of the first magnetoresistance effect element when a signal magnetic field is applied; wherein
each of the first magnetoresistance effect element and the second magnetoresistance effect element includes an upper electrode, a lower electrode, and a magnetoresistance effect multilayer body between the upper electrode and the lower electrode;
in the magnetoresistance effect multilayer body, a magnetized fixed layer having magnetization fixed in a certain direction, a first nonmagnetic layer, and a magnetized free layer whose magnetization direction changes according to the signal magnetic field are sequentially positioned;
the upper electrode is provided on a side of the magnetized free layer opposite to the first nonmagnetic layer in a lamination direction of the magnetoresistance effect multilayer body; and
each of the upper electrode and the lower electrode includes a magnetic material film including a magnetic material.

2. The magnetic sensor according to claim 1, wherein a first magnetic material film defining the upper electrode in the magnetic material film includes a multilayer film including a plurality of layers that are laminated.

3. The magnetic sensor according to claim 2, wherein the multilayer film includes an antiferromagnetic layer.

4. The magnetic sensor according to claim 1, wherein
each of the first magnetoresistance effect element and the second magnetoresistance effect element is configured to detect a magnetic field component in a direction orthogonal or substantially orthogonal to the lamination direction; and
the upper electrode and the magnetized free layer are magnetically coupled to each other.

5. The magnetic sensor according to claim 1, wherein
each of the first magnetoresistance effect element and the second magnetoresistance effect element is configured to detect a magnetic field component in the lamination direction; and
a second nonmagnetic layer is provided between the upper electrode and the magnetized free layer such that the upper electrode and the magnetized free layer are not magnetically coupled to each other.

6. The magnetic sensor according to claim 1, wherein the upper electrode has a disk shape.

7. The magnetic sensor according to claim 1, wherein a plurality of the upper electrodes are provided in a matrix.

8. The magnetic sensor according to claim 7, wherein each of the plurality of upper electrodes has a disk shape.

9. The magnetic sensor according to claim 8, wherein a diameter of each of the plurality of upper electrodes is about 9 μm.

10. The magnetic sensor according to claim 7, wherein an interval between centers of the plurality of upper electrodes is about 20 μm.

11. The magnetic sensor according to claim 1, wherein the lower electrode has a disk shape.

12. The magnetic sensor according to claim 1, wherein a plurality of the lower electrodes are provided in a matrix.

13. The magnetic sensor according to claim 12, wherein each of the plurality of upper electrodes has a disk shape.

14. The magnetic sensor according to claim 13, wherein a diameter of each of the plurality of upper electrodes is about 9 μm.

15. The magnetic sensor according to claim 12, wherein an interval between centers of the plurality of upper electrodes is about 20 μm.

16. The magnetic sensor according to claim 1, wherein the magnetic material include at least one of Co, Fe, or Ni as a main component.

17. The magnetic sensor according to claim 1, wherein the magnetoresistance effect multilayer body has a cylindrical or substantially cylindrical shape.

18. The magnetic sensor according to claim 17, wherein a diameter of the magnetoresistance effect multilayer body is about 3 μm.

19. The magnetic sensor according to claim 1, wherein each of the first magnetoresistance effect element and the second magnetoresistance effect element is a tunnel magneto resistance element.

20. The magnetic sensor according to claim 1, wherein the first nonmagnetic layer is a nonmagnetic tunnel barrier layer made of MgO.
